(19) United States
(12) Patent Application Publication
(10) Pub. No.: US 2018/0238971 A1
(43) Pub. Date: Aug. 23, 2018

(54) SYSTEM FOR TESTING POWER-OVER-ETHERNET PAIR-TO-PAIR UNBALANCE

(71) Applicant: SIFOS TECHNOOGIES, INC., Tewksbury, MA (US)

(72) Inventors: Kendrick R. Bennett, Tewksbury, MA (US); Peter G. Johnson, Andover, MA (US); John H. Skinner, Billerica, MA (US)

(21) Appl. No.: 15/901,101

(22) Filed: Feb. 21, 2018

Related U.S. Application Data
(60) Provisional application No. 62/461,932, filed on Feb. 22, 2017.

(51) Int. Cl. G01R 31/40

(52) U.S. Cl. CPC G01R 31/40; H04L 12/10

(57) ABSTRACT

Systems to assess pair-to-pair unbalance characteristics of an Ethernet powered device (PD) and pair-to-pair unbalance characteristics of an Ethernet power source (PSE) include a controller, a pair of controlled electrical resistance circuits each having a DC current measurement circuit to measure pair-to-pair unbalance and a calibration circuit.

### RELATED APPLICATIONS

This application claims the benefit of U.S. Provisional Application No. 62/461,932 filed Feb. 22, 2017, entitled SYSTEM AND METHOD FOR TESTING POWER-OVER-ETHERNET PAIR-TO-PAIR UNBALANCE which application is hereby incorporated herein by reference in its entirety.

### FIELD OF THE INVENTION

This invention relates generally to instrumentation for testing of network products and more specifically to instrumentation for parametric analysis of Power-over-Ethernet sources and loads and testing of Ethernet powered devices and Ethernet power-sourcing equipment.

### BACKGROUND

Power-over-Ethernet (PoE) is a technology whereby Ethernet switches, routers, and midspan injectors source DC power over Ethernet copper cabling to end terminal devices that operate from that power while also communicating to a computer network over that same Ethernet cabling. The IEEE 802.3 provides industry specifications to assure interoperability of Power-over-Ethernet equipment. The first two generations of IEEE 802.3 Clause 33 describing Power-over-Ethernet stipulated that power is delivered from a power sourcing equipment (PSE) interface (a port) to a powered device (PD) port utilizing two twisted wire pairs, one to feed current and a second wire pair to return current. It also stipulated that PD's must be designed to accept incoming current on any one of four twisted wire pairs that comprise an IEEE 802.3 Base-T medium dependent interface (MDI). Depending upon which wired pair sources DC current, a second particular wired pair would be designated to return DC current. To achieve this capability, PD's commonly use two full wave bridges with outputs combined in order to produce the proper supply polarities to PD circuitry. Given the two wire pair limitation, the maximum specified DC power available to PD's is 25.5 watts.

A third generation IEEE 802.3 Power-over-Ethernet specification removes the stipulation that power is fed on just two wire pairs and allows DC power to be fed from PSE to PD on all four wire pairs that make up the Ethernet Base-T MDI. This means that two wire pairs source incoming DC current to a PD and the other two wire pairs return DC current from the PD. This is done to enable delivery of higher power to PD's and also to reduce average power loss in Ethernet copper cabling. With 4-pair powering, PD's drawing 51 watts can operate on the same cabling utilized previously for powering PD's up to 25.5 watts. With certain cabling constraints, 4-pair powering will enable PD's that draw over 70 watts to operate on a network.

One significant challenge associated with 4-pair PoE is to assure that current sourced from a PSE to a PD, and also current returned from a PD to a PSE, is split approximately evenly between two wire pairs in each direction. This is critically important for two reasons. First, many PSE's that provide 4-pair power will monitor DC current on a per-wire-pair basis in order to determine if either too much or too little current is flowing. PSE's must act as circuit breakers that shut down power if too much current flows on a wire pair. If it is unclear how DC current splits between two wire pairs, then the PSE has no way of determining that an excess of current is flowing to the PD. Second, given the higher power PD loads, if total DC current is over-concentrated in one wire pair, there is the potential for electrical wear-and-tear to cabling and connectors. In a highly unbalanced system, DC currents in a single wire pair could exceed 1.5 amps.

There are three entities that contribute to the split of DC current on parallel wire pairs. First is the cabling and connectors that mate to the PSE and to the PD. To address pair-to-pair DC resistance unbalance in cabling and connectors, the standards bodies associated with Ethernet cabling will publish new industry specifications that govern existing cabling systems. For example, such specification may state that the maximum DC resistance difference between wire pairs in any path exceeding a certain electrical length will be 7 percent.

The second entity that contributes to pair-to-pair DC current unbalance is the PSE. Differences in path resistance that include Ethernet MDI characteristics, transformers, and PoE power sourcing circuitry will affect the split of DC current. The IEEE 802.3 standard specifies maximum variations in PSE pair-to-pair current unbalance that can be tolerated given that the PSE is providing 4-pair power to cabling systems and PD's that are known to be compliant for pair-to-pair unbalance.

The third entity that that contributes to pair-to-pair DC current unbalance is the PD. Differences in path resistance that include Ethernet MDI characteristics, transformers, and full wave bridges will affect the split of DC current. The IEEE 802.3 standard specifies maximum variations in PD pair-to-pair current unbalance that can be tolerated given that the PD is drawing 4-pair power from a cabling system and a PSE that are both known to be compliant for pair-to-pair unbalance.

While cabling and connectors affect DC current unbalance through unbalanced DC resistance, the effects of cabling and connectors is relatively simple to anticipate and analyze. This is not the case with PSE's and PD's where DC current unbalance is affected both by DC resistances and by semiconductor characteristics. Furthermore, the impact of PSE's and PD's to overall DC current unbalance is more pronounced typically when cable lengths are very short since the fixed resistive loss of the cabling and connectors becomes a smaller component to the total current unbalance equation.

### SUMMARY

Configurations disclosed herein substantially overcome the shortcomings of conventional testing methods. In particular, a POE test solution as disclosed herein provides a method of comprehensively testing Ethernet powered devices which operate under IEEE 802.3 clause 145 standards.

Because of the difficulty in specifying DC current unbalance as an attribute of a physical interface in the PSE and PD, the IEEE 802.3 specification addresses DC current unbalance through a testing procedure whereby the PSE and the PD are connected to apparatus that model DC resistance unbalance of the other two entities. Testing is very involved because DC current unbalance must be measured across a continuum of resistance unbalance scenarios where both the combined parallel resistance and the degree of pair-to-pair resistance unbalance are varied. This is repeated for both the source, or high-side DC current wire pairs and the return or low-side DC current wire pairs. PD current unbalance testing also requires variation of PoE source voltages while PSE current unbalance testing also requires variation of PoE current loads.

Furthermore, the task requires precision control of DC resistances that range across small values, for example, 0.2 to 7 ohms while supporting currents of 1 amp or higher. Because the controlled DC resistances create 100 percent of the intended DC current unbalance, the test circuit must assure that any power sources or power loads utilized in the testing do not introduce any unknown amounts of DC current unbalance. Theoretical testing methods shown in the IEEE 802.3 specification, show ammeters used in testing procedures. The use of an ammeter could unfortunately introduce an unacceptable level of uncertainty in any current unbalance measurement or test.

In one embodiment, a system to assess pair-to-pair unbalance characteristics of an Ethernet powered device (PD) under test includes a controller, a pair of controllable electrical resistances wherein each controllable electrical resistance includes an input port, a control port coupled to the controller, an output port, and a DC current measurement circuit. The system further includes a reference power input port that includes a first power supply input connection having a first polarity coupled to both input ports of the pair of controllable electrical resistances and a second power supply input connection having a second different polarity coupled to a pair of reference power input port return paths. The system further includes an Ethernet powered device port that includes a first pair of Ethernet powered device port coupling circuits, each coupled to corresponding output ports of the pair of controllable electrical resistances and a second pair of Ethernet powered device port coupling circuits, each coupled to corresponding return paths in the reference power input port. Such a system enables rapid progression through many possible configurations of pair-to-pair unbalance external to the Ethernet PD while measuring the current that flows in each pair as a result of the pair-to-pair unbalance synthesized and also the pair-to-pair unbalance added by the Ethernet PD.

Implementations may include one or more of the following features. The system where each DC current measurement circuit is disposed to minimize an electrical resistance in a connection between the reference power input port and the Ethernet powered device port. The system where the reference power input port further includes: a first pair of reference power input port coupling circuits, each coupled to corresponding input ports of the pair of controllable electrical resistances; a second pair of reference power input port coupling circuits, each coupled to corresponding reference power input port return paths; and an Ethernet MDI coupled to the first pair of reference power input port coupling circuits and the second pair of reference power input port coupling circuits. The system further including a switch to selectively connect each one of the first pair of reference power input port coupling circuits to a common reference node. The system further including at least one DC-isolated path disposed between each reference power input port coupling circuit and each corresponding Ethernet powered device port coupling circuit, for transferring Ethernet data signaling between the reference power input port and the Ethernet powered device port. The system further including: a first switch coupled to the controller to connect selected ones of the first pair of reference power input port coupling circuits and selected ones of the second pair of reference power input port coupling circuits to one of: input ports of selected ones of the pair of controllable electrical resistances; and selected ones of the pair of reference power input port return paths; a second switch coupled to the controller to connect selected ones of the first pair of Ethernet powered device port coupling circuits and selected ones of the second pair of Ethernet powered device port coupling circuits to one of: output ports of selected ones of the pair of controllable electrical resistances; and selected ones of the pair of reference power input port return paths.

In another embodiment, the system further includes an Ethernet patch cable coupling the reference power input port and the Ethernet powered device port and a calibration circuit coupled to the controller having a switched coupling to the input port of at least one controllable electrical resistance and a switched coupling to at least one coupling circuit within the reference power source port and a pair of voltage sense inputs to measure the voltage drop between the input port of at least one controllable electrical resistance and at least one Ethernet MDI in the reference power source port. Such a system measures and adjusts for non-controlled resistances that may include coupling circuits, connectors, and an Ethernet patch cable coupling the system to an Ethernet powered device under test or to an Ethernet power source under test. The exemplary calibration circuit interrupts the coupling between the reference power input port and the input port of each controllable electrical resistance, and then measures the electrical resistance between the input port of each controllable electrical resistance and the reference power input port while an Ethernet patch cable couples the Ethernet powered device port to the reference power input port.

In another embodiment, the calibration circuit further includes at least one DC current source to insert a DC current into the input port of the same one of the pair of controllable electrical resistances and to receive the DC current from at least one coupling circuit in the reference power input port. In yet another embodiment, each of the pair of controllable electrical resistances is configurable to system source resistances for evaluating the Ethernet powered device as described within an IEEE 802.3 clause 145 specification to create pair-to-pair current unbalance in wire pair connections of the same voltage polarity attached to the Ethernet powered device port coupling circuits. The system may also include where each DC current measurement circuit provides at least one of average and instantaneous measurements. The system where electrical connections within the reference power input port, the pair of controllable electrical resistances, and the Ethernet powered device port are configured to add less than about 0.2 ohms series electrical resistance to a resistance produced by at least one of the pair of controllable electrical resistances.

In certain embodiments of the system, the reference power input port and the reference power source port include coupling circuits and Ethernet medium dependent interfaces for connection to DC power supplies or DC power loads that connect to the system using Ethernet patch cables. Certain embodiments of the system include features to minimize any electrical resistance that is not controlled because the controllable electrical resistances that produce pair-to-pair unbalance are very small, ranging down to one tenth of one ohm. Such features may include very low resistance connections, very low resistance switches, and very low resistance coupling circuits that may further include electrical transformers or other such magnetic coils.

In another embodiment, the system can be configured to assess the pair-to-pair unbalance characteristics of an Ethernet power sourcing port (PSE) under test. In this embodiment, a reference power load port replaces the reference power input port and includes a first power load connection having a first polarity coupled to both input ports of the pair of controllable electrical resistances and a second power load connection having a second different polarity coupled to a pair of reference power load port return paths. Further, an Ethernet power source port replaces the Ethernet powered device port and includes a first pair of Ethernet power source port coupling circuits, each coupled to corresponding output ports of the pair of controllable electrical resistances and a second pair of Ethernet power source port coupling circuits, each coupled to corresponding return paths in the reference power load port.

Implementations may include one or more of the following features. The system where each DC current measurement circuit is disposed to minimize an electrical resistance in a connection between the reference power load port and the Ethernet power source port. The system where the reference power load port further includes: a first pair of reference power load port coupling circuits, each coupled to corresponding output ports of the pair of controllable electrical resistances; a second pair of reference power load port coupling circuits, each coupled to corresponding reference power load port return paths; and an Ethernet MDI coupled to the first pair of reference power load port coupling circuits and the second pair of reference power load port coupling circuits. The system further including a switch to selectively connect each one of the first pair of reference power load port coupling circuits to a common reference node. The system further including at least one DC-isolated path disposed between each corresponding reference power load port coupling circuit and each corresponding Ethernet power source port coupling circuit for transferring Ethernet data signaling between the reference power load port and the Ethernet power source port. In another embodiment, the system further includes: a first switch coupled to the controller to connect selected ones of the first pair of reference power load port coupling circuits and selected ones of the second pair of reference power load port coupling circuits to one of: output ports of selected ones of the pair of controllable electrical resistances; and selected ones of the pair of reference power load port return paths; a second switch coupled to the controller to connect selected ones of the first pair of Ethernet power source port coupling circuits and selected ones of the second pair of Ethernet power source port coupling circuits to one of: input ports of selected ones of the pair of controllable electrical resistances; and selected ones of the pair of reference power load port return paths. The system may also include an Ethernet patch cable coupling the reference power load port and the Ethernet power source port.

In another embodiment for Ethernet power source testing, the system includes a similar calibration circuit (as described above) that interrupts the coupling between the reference power load port and the input port of each controllable electrical resistance, and then measures the electrical resistance between the input port of each controllable electrical resistance and the reference power load port while an Ethernet patch cable couples the Ethernet power source port to the reference power load port. In this embodiment, the system further includes an Ethernet patch cable coupling the reference power load port and the Ethernet power source port and a calibration circuit coupled to the controller including a switch selectively coupling an input port of at least one of the pair of controllable electrical resistances to a source connection of the calibration circuit and a switch selectively coupling a DC current return in the calibration circuit to the reference power load port. The system further includes a pair of voltage sense inputs to measure a voltage drop between an output port of a same one of the pair of the controllable electrical resistances and the Ethernet MDI in the reference power load port.

In the aforementioned embodiments, measurements of electrical resistance that include uncontrolled resistive components may be applied to adjust DC current unbalance measurements performed during testing in a manner that compensates for those uncontrolled resistive components. In embodiments disclosed herein, calibration involves sourcing a known current and measuring a voltage drop across the full circuit that includes the programmable resistance, test port interfaces, and a patch cable. From these measurements an actual resistance of certain components can be calculated.

In another embodiment, here the calibration circuit further includes at least one DC current source to insert a DC current into the output port of the same one of the pair of controllable electrical resistances and to receive the DC current from at least one coupling circuit in the reference power load port. In still another embodiment, each of the pair of controllable electrical resistances are configurable to provide system load resistances for evaluating the Ethernet power source as described within an IEEE 802.3 clause 145 specification to create a pair-to-pair current unbalance in wire pair connections of the same voltage polarity attached to the Ethernet power source port coupling circuits. In yet another embodiment, the system may also include where each DC current measurement circuit provides at least one of an average and an instantaneous measurement. The system where electrical connections within the reference power load port, the pair of controllable electrical resistances and the Ethernet power source port are configured to add less than about 0.2 ohms series electrical resistance to a resistance produced by at least one of the pair of controllable electrical resistances.

The features of the invention, as explained herein, may be employed in a standalone test instrument or can be combined as a subsystem with other test instruments. The embodiments disclosed herein, may be employed in software and hardware systems such as those manufactured by Sifos Technologies Inc. of Tewksbury Mass.

Additionally, although each of the different features, techniques, configurations, etc. herein may be discussed in different places of this disclosure, it is intended that each of the concepts can be executed independently of each other or in combination with each other.

Accordingly, the present invention can be embodied and viewed in many different ways. Note also that this Summary section herein does not specify every embodiment and/or incrementally novel aspect of the present disclosure or claimed invention. Instead, this Summary only provides a preliminary discussion of different embodiments and corresponding points of novelty over conventional techniques. For additional details and/or possible perspectives (permutations) of the invention, the reader is directed to the Detailed Description section and corresponding figures of the present disclosure as further discussed below.

### BRIEF DESCRIPTION OF THE DRAWINGS

The foregoing and other objects, features and advantages of the invention will be apparent from the following more particular description of embodiments of the methods and apparatus for testing network interfaces, as illustrated in the accompanying drawings and figures in which like reference characters refer to the same parts throughout the different views. The drawings are not necessarily to scale, with emphasis instead being placed upon illustrating the embodiments, principles and concepts of the methods and apparatus in accordance with the invention.

FIG. 1 is a block diagram of a system to assess pair-to-pair DC current unbalance, including two controllable electrical resistances, for testing a powered device (PD) according to embodiments disclosed herein;

FIG. 2 shows further details of the system of FIG. 1 including a reference power input port, an Ethernet powered device port and the two controllable electrical resistances;

FIG. 3 shows further details of the reference power input port of FIG. 1 including coupling circuits, an MDI interface for connection to an Ethernet Power Source, and a common node to minimize any unknown resistance unbalance effects of the system;

FIGS. 4A and 4B are block diagrams showing switches to provide a common reference node the reference power input port of FIG. 2;

FIG. 5 is a block diagram of the system of FIG. 2 further showing DC-isolated paths for transfer of Ethernet data signaling between the reference power source port and the Ethernet powered device port;

FIG. 6 is a block diagram of the system of FIG. 2 further including switches for selecting the wire pairs that are coupled to the controllable electrical resistance circuits;

FIG. 7 is a block diagram showing details of the calibration circuit of FIG. 1 for calibrating total resistance, including the Ethernet patch cable used to connect the Ethernet Powered device port to an Ethernet powered device;

FIG. 8 is a block diagram of a system to assess pair-to-pair DC current unbalance, including two controllable electrical resistances, for testing an Ethernet Power Source according to embodiments disclosed herein;

FIG. 9 is a block diagram showings further details of the system of FIG. 8 including the reference power load port, the Ethernet power source port, and two controllable electrical resistances;

FIG. 10 is a block diagram showings further details of the system of FIG. 8 showing an MDI interface for connection to an Ethernet Power Source, and adds a common node which negates any unknown DC current unbalance effects of that system;

FIGS. 11A and 11B are block diagrams showing switches to provide a common reference node of the reference power load port of FIG. 10;

FIG. 12 is a block diagram of FIG. 2 showing DC-isolated paths for transferring Ethernet data signaling between the reference power load port and the Ethernet power source port;

FIG. 13 shows switches FIG. 8 for selecting the wire pairs that the controllable electrical resistance circuits will be applied to; and

FIG. 14 is a block diagram showing the calibration circuit of FIG. 8 for calibrating total resistance, including the Ethernet patch cable used to connect the Ethernet power source port to an Ethernet power source.

### DETAILED DESCRIPTION

Embodiments disclosed herein provide instruments and processes for testing of Ethernet powered devices and power sourcing equipment (PSE). The systems for assessing pair-to-pair unbalance characteristics of an Ethernet powered device (PD) under test and an Ethernet power source (PSE) under test precisely and controllably simulate external pair-to-pair unbalance characteristics that are described in the IEEE 802.3 standard clause 145. Furthermore, the system measures DC current in two powered pairs to determine if the DC current in any one pair exceeds limits prescribed by the above referenced IEEE 802.3 standard. Excess unbalance current will interfere with the interoperability of Ethernet powered devices and Ethernet power sources.

Unlike other forms of specification compliance testing, the pair-to-pair unbalance contribution of an Ethernet powered device or and Ethernet power source can only be assessed in the presence of controlled external pair-to-pair unbalance simulation. Depending upon the tested device, a variety of unbalance simulations are presented and may include powered pair and polarity selection, simulated external resistance unbalance level, reference power source voltage, and reference power load current. Furthermore, these simulations should be precisely performed using instrument grade equipment.

Embodiments disclosed herein minimize uncontrolled resistance in order to maximize the accuracy of external pair-to-pair unbalance simulation. These embodiments include features to minimize any electrical resistance that is not controlled because the controllable electrical resistances that simulate pair-to-pair unbalance are very small, ranging down to one tenth of one ohm. Such features may include very low resistance connections, very low resistance switches, and very low resistance coupling circuits. Embodiments disclosed herein implement DC current measurements in a manner that does not add any uncontrolled resistance to the simulated external pair-to-pair resistance unbalance. Further, embodiments disclosed include calibration circuits to enable the characterization of uncontrolled resistance as may result from electrical connections, switches, coupling circuits, and test cable connections. This characterization is then be used to compensate DC current measurements performed during testing so that the accuracy of the simulated pair-to-pair unbalance is further improved.

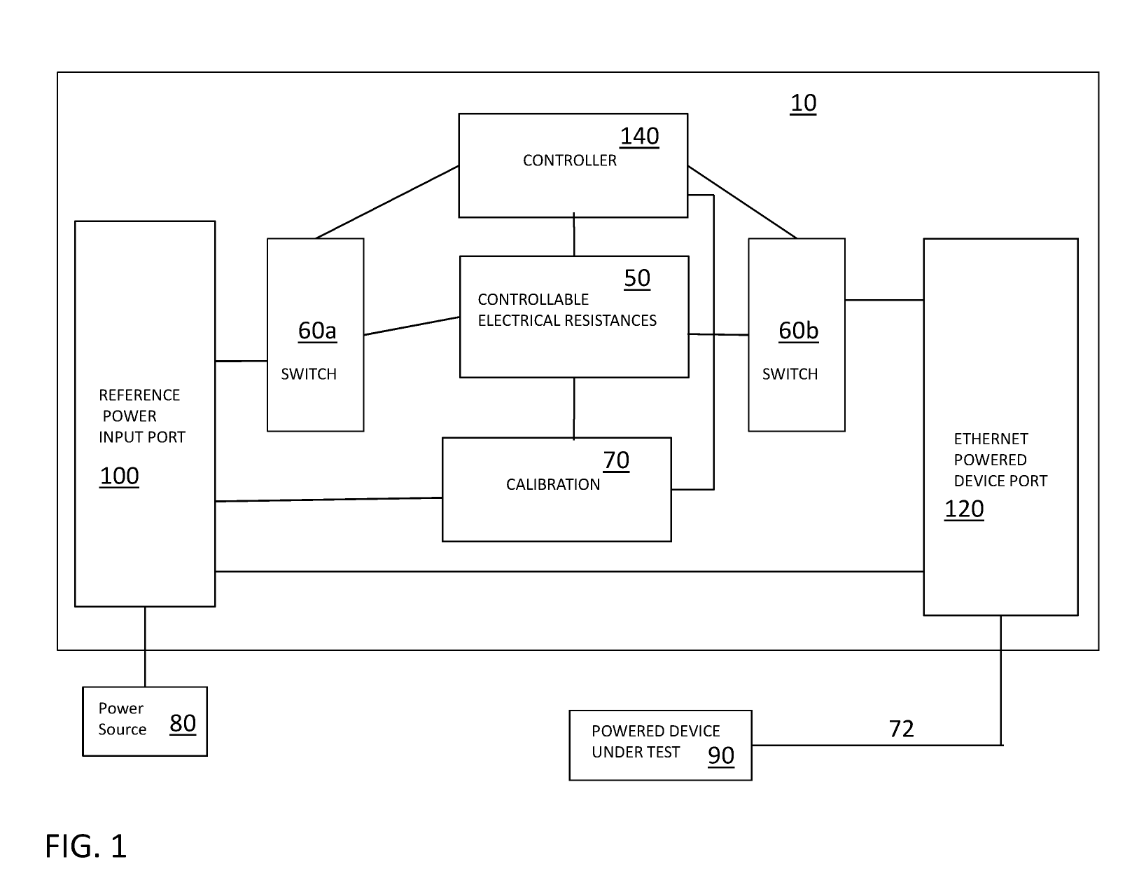

Now referring to FIG. 1, in one embodiment, a system 10 to assess pair-to-pair unbalance characteristics of an Ethernet powered device (PD) under test 90 (also referred to as the PD under test 90) connected to an Ethernet powered device port 120 with an Ethernet patch cable 72. The system 10 includes a controller 140 coupled to controllable electrical resistances 50, to a pair of switches 60a and 60b and to a calibration subsystem 70. The system 10 further includes a reference power input port 100 coupled to switch 60a and an Ethernet powered device port 120 coupled to switch 60b. Switch 60a selectively couples the controllable electrical resistances 50 to the reference power input port 100 and Switch 60b selectively couples the controllable electrical resistances 50 to the Ethernet powered device port 120. The system 10 further includes power source 80 coupled to the reference power input port 100 to provide the power to the PD under test 90.

The calibration process uses the Ethernet patch cable 72, connecting the reference power input port 100 and the Ethernet powered device port 120. The system 10 is able to accurately assess the pair-to-pair unbalance characteristics of the PD under test 90 by calibrating the effects of the switches 60a and 60b, the Ethernet powered device port 120, and the Ethernet patch cable 72. In one embodiment the controller 140 is a microcontroller and in another embodiment the controller 140 is an interface to an external controlling device, for example, a computer.

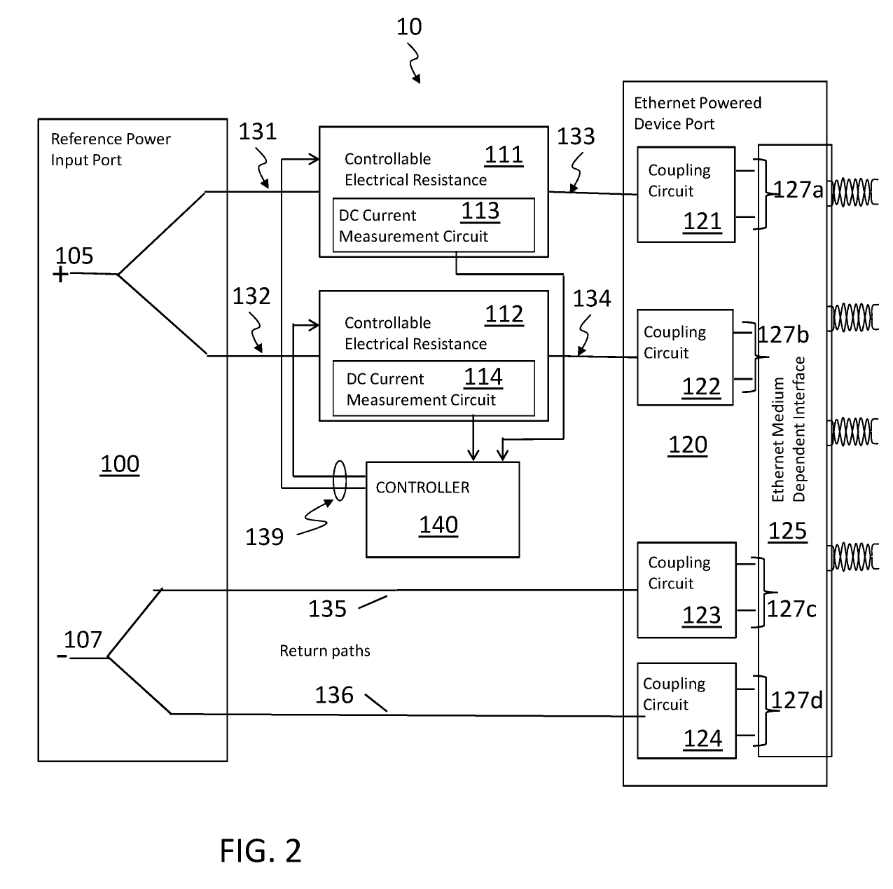

Referring to FIG. 2, the system 10 to assess pair-to-pair unbalance characteristics of the PD under test 90 of FIG. 1 includes in more detail the controller 140 coupled to the controllable electrical resistances 50 which includes a pair of controllable electrical resistances 111 and 112 each having an input port 131 and 132, a control port 139 coupled to the controller 140, output ports 133 and 134, and DC current measurement circuits 113 and 114. Each DC current measurement circuit 113 and 114 is configured to minimize an electrical resistance in a connection between the reference power input port 100 and the Ethernet powered device port 120.

The reference power input port 100 further includes a first power supply input connection 105 having a first polarity coupled to both input ports 131 and 132 of the pair of controllable electrical resistances 111 and 112, respectively, and a second power supply input connection 107 having a second different polarity coupled to a pair of reference power input port return paths 135 and 136, respectively. The Ethernet powered device port 120 further includes a first pair of Ethernet powered device port coupling circuits 121 and 122, each coupled to corresponding output ports 133 and 134 of the pair of controllable electrical resistances 111 and 112, respectively, and a second pair of Ethernet powered device port coupling circuits 123 and 124, each coupled to corresponding return paths 135 and 136 of the pair of reference power input port return paths.

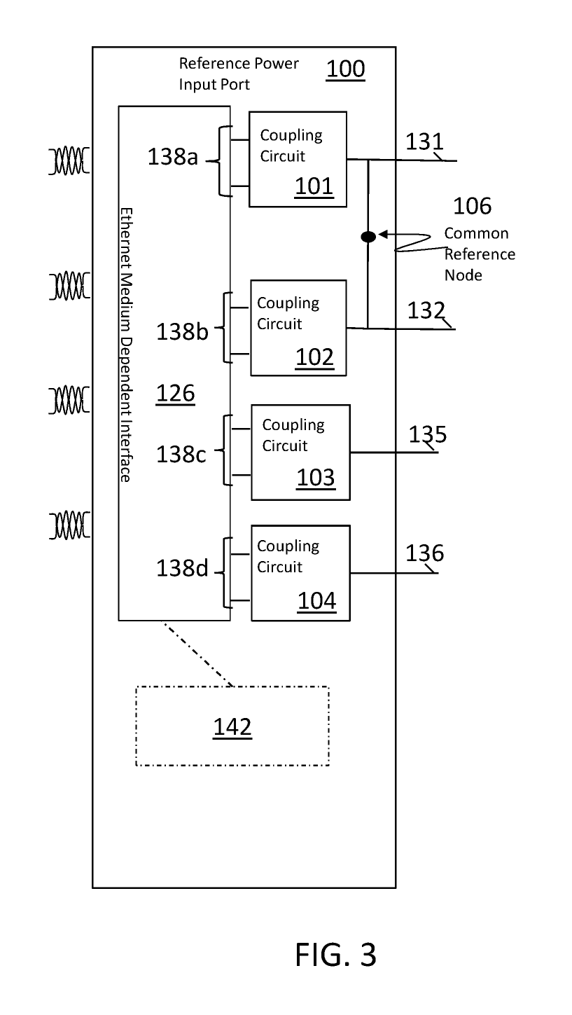

In operation during a test, power over Ethernet (PoE) power required for powering the PD under test 90 is provided by reference power input port 100. In one embodiment of the reference power input port 100, the incoming current is generated by a power source external to the reference power input port 100 and the return current from the PD under test 90 returns to that same external power source via return paths 135 and 136 of the reference power input port 100. In another embodiment of the reference power input port 100, the incoming current is generated by an optional internal power source 142 (FIG. 3) to the reference power input port 100 and the return current from the PD returns to that same optional internal power source 142. The DC current measurement circuits 113 and 114 provide average and instantaneous measurements. The pair of controllable electrical resistances 111 and 112 is configurable to system source resistances for evaluating the Ethernet powered device as described within the IEEE 802.3 clause 145 specification to create pair-to-pair resistance unbalance in wire pairs attached to the Ethernet powered device port coupling circuits.

The components in the system 10 to assess the DC current unbalance produced by the PD under test 90 while powered from four wire pairs, are controllable electrical resistances 111 and 112 with an input port 131 and 132 respectively, with an output 133 and 134 respectively and DC current measurement circuits 113 and 114 respectively. In order to produce controlled DC current unbalance, controllable electrical resistances 111 and 112 create resistance unbalance by being set to unmatched resistances. The controller 140 is utilized to configure each of the controllable electrical resistances 111, and 112, which operate independently, using control port 139 so that resistances may be rapidly reconfigured during testing.

In one embodiment, the controller 140 may facilitate system operation with an external computer and can have an internal graphical user interface (GUI) or the GUI can be supplied by the external computer (not shown) or an additional test instrument (not shown). In one embodiment, the controller 140 configures an electronically controllable resistance element. In another embodiment controller 140 actuates switching (not shown) to configure a set of fixed resistors.

The Ethernet powered device port 120 provides the system interface to the PD under test 90, via the Ethernet patch cable 72. The Ethernet powered device port 120 includes an Ethernet medium dependent interface 125 and two coupling circuits 121 and 122, to insert DC current into two wire pair connections 127a and 127b and two coupling circuits 123 and 124, to receive return current through wire pair connections 127c and 127d (wire pairs are coupled into the wire pair connections) from the Ethernet patch cable 72 connected to the PD under test 90. In one embodiment, each coupling circuit 121, 122, 123, and 124 includes an Ethernet transformer with primary coil center taps (not shown) as is known in the art. Other embodiments may employ multiple magnetic coils in each coupling circuit in order to minimize DC resistance.

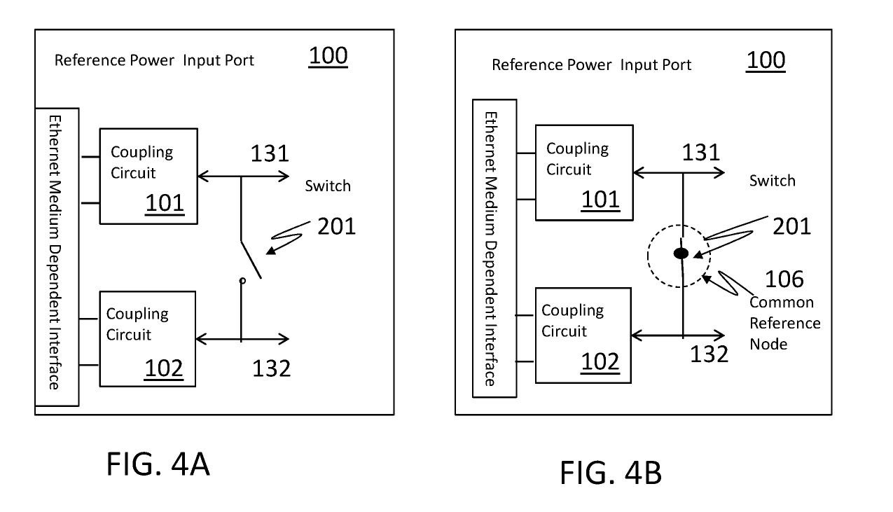

In one embodiment voltages are measured across a known portion of the controllable electrical resistances 111 and 112. These measurements are used to obtain DC current measurements without adding any uncontrolled resistance that would otherwise distort the expected pair-to-pair unbalance. In one embodiment, the electrical connections within the reference power input port 100, the pair of controllable electrical resistances 111 and 112, and the Ethernet powered device port 120 are configured to add less than about 0.2 Ohms of uncontrolled series electrical resistance to a resistance produced by the controllable electrical resistances 111 and 112. In a further embodiment, this is accomplished by a combination of thick circuit board traces, the common reference node (described below in conjunction with FIGS. 4A and 4B), and redundant parallel connections in switches and coils.

Referring to FIG. 3, the reference power input port 100 further includes a first pair of reference power input port coupling circuits 101 and 102, each coupled to corresponding input ports 131 and 132 of the pair of controllable electrical resistances 111 and 112, respectively, a second pair of reference power input port coupling circuits 103 and 104, each coupled to corresponding reference power input port return paths 135 and 136 respectively, and an Ethernet MDI 126 coupled to the first pair of reference power input port coupling circuits 101 and 102 and the second pair of reference power input port coupling circuits 103 and 104 via wire pair connections 138a-138d, respectively. In this configuration coupling circuit 101 is connected to input port 131, coupling circuit 102 is connected to input port 132, coupling circuit 103 is connected to return path 135 and coupling circuit 104 is connected to return path 136. The reference power input port 100 includes a common reference node 106, which in this configuration provides a low resistance connection between input port 131 and input port 132. The common reference node 106 assures that causes of DC current unbalance that might exist within the reference power input port, or in an external power source 80 connected to the reference power input port 100 are greatly minimized so that there is almost no resistance unbalance between controllable electrical resistance input ports 131 and 132. This means that the controllable electrical resistances 111 and 112, in tandem with the PD under test 90, will govern the amount of DC current unbalance between wire pair connections 127a-127b at the Ethernet MDI 125 in the Ethernet powered device port 120.

The PoE power required for powering the PD under test 90 is provided through the reference power input port 100. Incoming current is extracted from two wire pair connections 138a and 138b using the coupling circuits 101 and 102 while return current from the PD under test 90 is inserted into the coupling circuits 103 and 104. In one embodiment, the coupling circuits 101-104, include an Ethernet transformer with primary coil center taps.

Referring now to FIGS. 4A and 4B, the reference power input port 100 further includes a switch 201 disposed between controllable electrical resistance input ports 131 and 132. Switch 201 connects the controllable electrical resistance input ports 131 and 132 together to create a common reference node 106. Switch 201 then allows the common reference node connection to be made only after a PD has been detected and classified and has entered a normal powering state of operation. This prevents the common reference node from interfering with the PD detection and classification processes that may precede application of operating power. In one embodiment, switch 201 is deployed to prevent accidental connection of two wire pairs that are opposite voltage polarities.

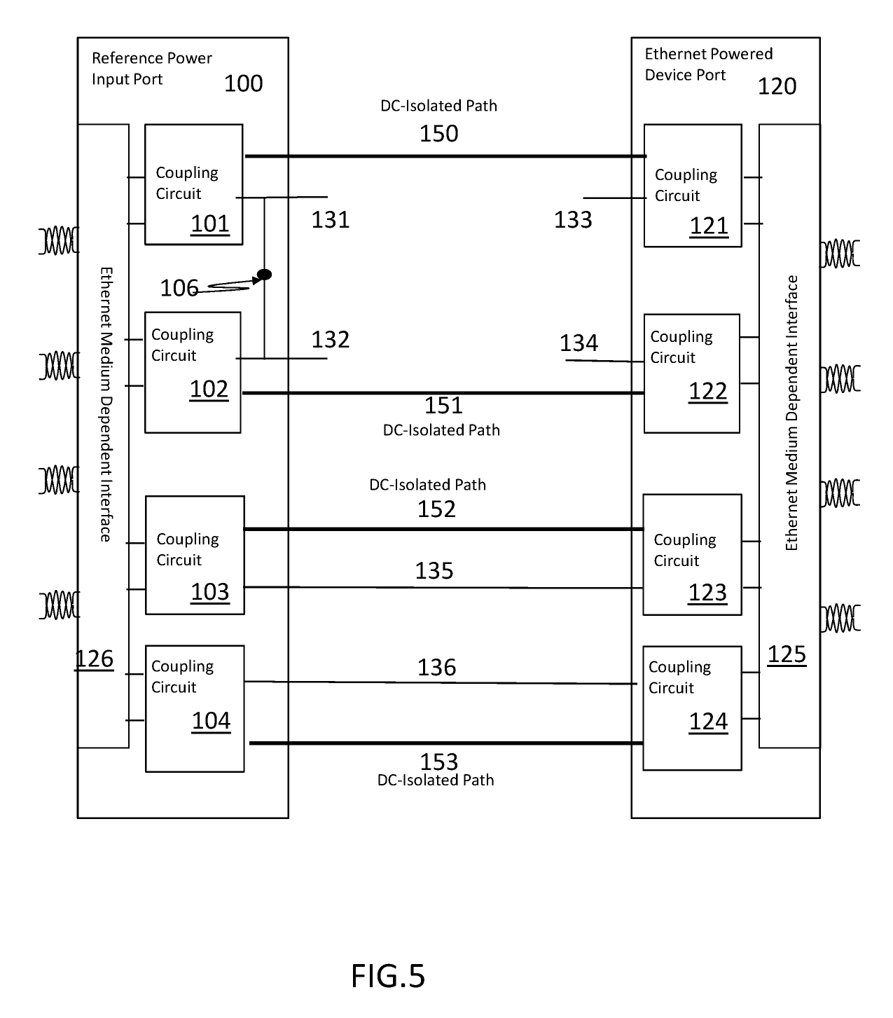

Now referring to FIG. 5, the system 10 further includes DC isolated paths 150, 151, 152, and 153 between coupling circuits 101, 102, 103, 104 and 121, 122, 123, 124, respectively, for transferring Ethernet data signaling between the reference power input port 100 and the Ethernet powered device port 120. These DC isolated paths 150-153 provide a path for Ethernet data signaling between the reference power input port 100 and the Ethernet Powered device port 120. In one embodiment, Ethernet data signaling is used to control the operating characteristics of the PD under test 90. In a further embodiment, control of the operating characteristics of the PD under test 90 may include negotiating power with PoE data-link layer classification. Control of operating characteristics of the PD under test 90 can be essential to obtaining the highest possible current measurements.

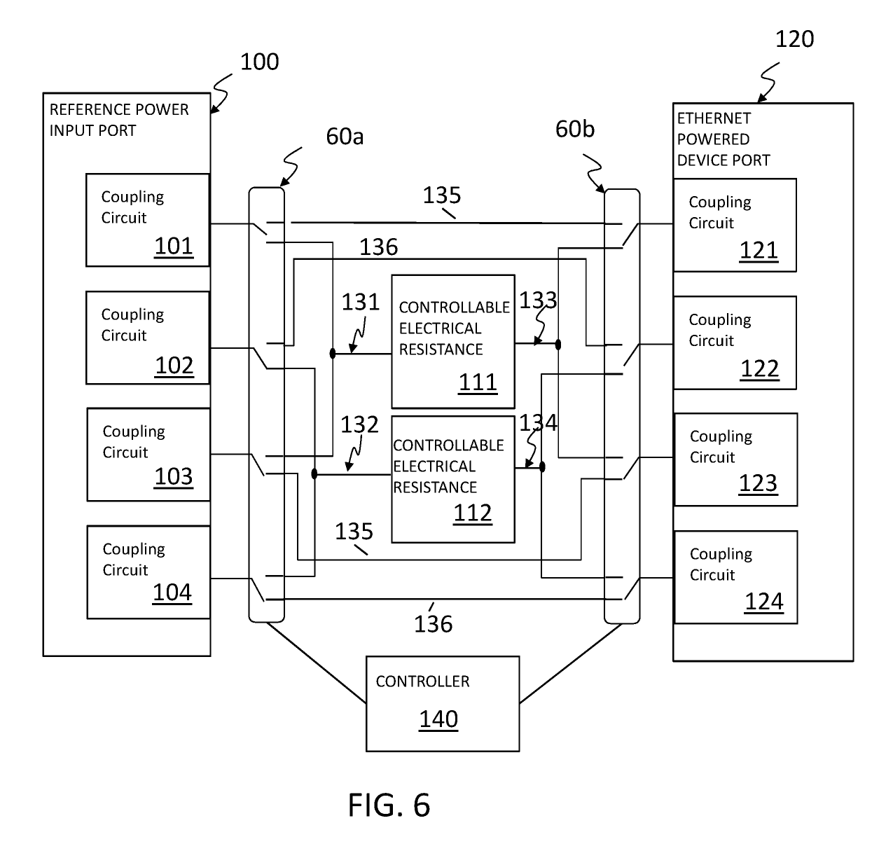

Now referring to FIG. 6, system 10 further includes a first switch 60a coupled to the controller 140 to connect selected ones of the first pair of reference power input port coupling circuits 101 and 102 and selected ones of the second pair of reference power input port coupling circuits 103 and 104 to either the input ports 131 and 132 of selected ones of the pair of controllable electrical resistances 111 and 112 or selected ones of the pair of reference power input port return paths 135 and 136. System 10 further includes a second switch 60b coupled to the controller 140 to connect selected ones of the first pair of Ethernet powered device port coupling circuits 121 and 122 and selected ones of the second pair of Ethernet powered device port coupling circuits 123 and 124 to either output ports 133 and 134 of selected ones of the pair of controllable electrical resistances 111 and 112 or to selected ones of the pair of reference power input port return paths 135 and 136.

In operation switches 60a and 60b connect controllable electrical resistance 111 between coupling circuits 101 and 121 or between coupling circuits 103 and 123 and connect controllable electrical resistance 112 between coupling circuits 102 and 122 or between coupling circuits 104 and 124. The selected switch settings connect the controllable electrical resistances 111 and 112 to paths of the same polarity when an unbalance assessment is made. Using switches 60a and 60b, each of the pair of controllable electrical resistances 111 and 112 is configurable to system source resistances for evaluating the PD under test 90 in various wiring configurations as described within an IEEE 802.3 clause 145 specification to create pair-to-pair resistance unbalance in wire pairs attached to the Ethernet powered device port coupling circuits 121-124.

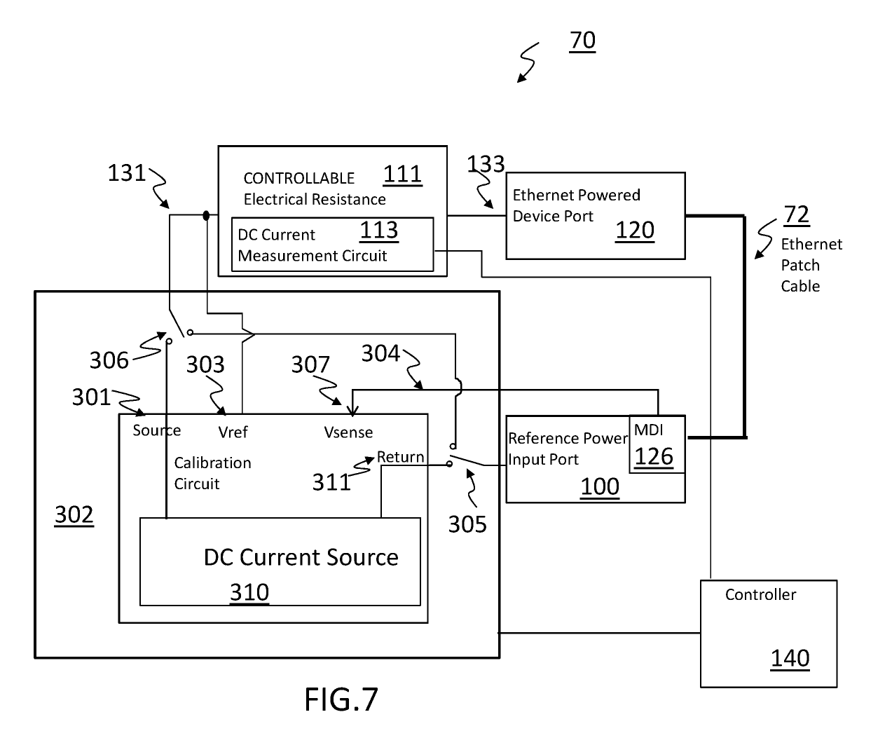

Now referring to FIG. 7, the calibration subsystem 70 of system includes an Ethernet patch cable 72 coupling the reference power input port 100 and the Ethernet powered device port 120; and a calibration circuit 302 coupled to the controller 140. The calibration circuit 302 also includes a DC current source 310 having a DC current source 301 (also referred to as DC current source connection 301) and a DC current return 311 (also referred to as DC current return connection 311), to provide at least one current level, here, to the controllable electrical resistance 111. The calibration circuit 302 further includes a switch 306 to selectively couple the controllable electrical resistance 111 input port 131 to the DC current source connection 301, and a switch 305 to selectively couple at least one coupling circuit 101-104 within the reference power input port 100 to the DC current return connection 311. Switches 305 and 306 interrupt the normal connection between the reference power input port 100 and the input port 131 of the controllable electrical resistance 111 to insert the DC current source 310. The calibration circuit 302 further includes a pair of voltage sense inputs (a voltage sense input 307 and a voltage reference input 303) that are used to measure a voltage drop between the Ethernet MDI 126 in the reference power input port 100 and the input port 131 of the controllable electrical resistance 111. In a further embodiment of the calibration subsystem 70, additional switches within the calibration circuit 302 would allow the DC current source 310 to be connected to the input port 132 of controllable electrical resistance 112 and to a different coupling circuit within the reference power input port 100.

In operation, the calibration circuit 302 provides DC current source connection 301 and return connections 304, through which a DC current passes and the calibration circuit 302 measures an actual electrical resistance of the controllable electrical resistance 111, the Ethernet powered device port 120, and the Ethernet patch cable 72. The DC current source 301 is connected to the input port 131 of the controllable electrical resistance 111. The output 133 of the controllable electrical resistance 111 passes the current to one of the coupling circuits 121, 123 of the Ethernet Powered Device port 120, which passes the current through one of the wire pairs of an Ethernet patch cable 72. The Ethernet patch cable 72 is connected between the Ethernet Powered Device Port 120 and the Reference Power Input Port 100. The current passes through the Ethernet Patch Cable 72, the Reference Power Input Port 100, and to the DC current return connection 311 at the calibration circuit 302. Voltage is sensed at the Ethernet MDI 126, to determine a total voltage drop between the input port 131 of the controllable electrical resistance 111 and the end of the Ethernet patch cable 72 connected to the MDI 126 in the reference power input port. The DC current is measured by the DC current measurement circuit 113, connected to the controller 140.

The total voltage drop is then combined with the DC current measurement to compute the actual electrical resistance between the input port 131 of the controllable electrical resistance 111 and the end of the Ethernet patch cable 72 connected to the reference power input port 100. In a further embodiment of the calibration subsystem, a similar process is used to measure the actual electrical resistance between the input port 132 of the controllable electrical resistance 112 and the end of the Ethernet patch cable 72 connected to the MDI 126 in the reference power input port 100. The actual resistances measured may then be subsequently applied during pair-to-pair unbalance testing of a PD to adjust measured DC unbalance currents to compensate for any uncontrolled resistances present in electrical connections, the Ethernet powered device port 120 and the Ethernet patch cable 72.

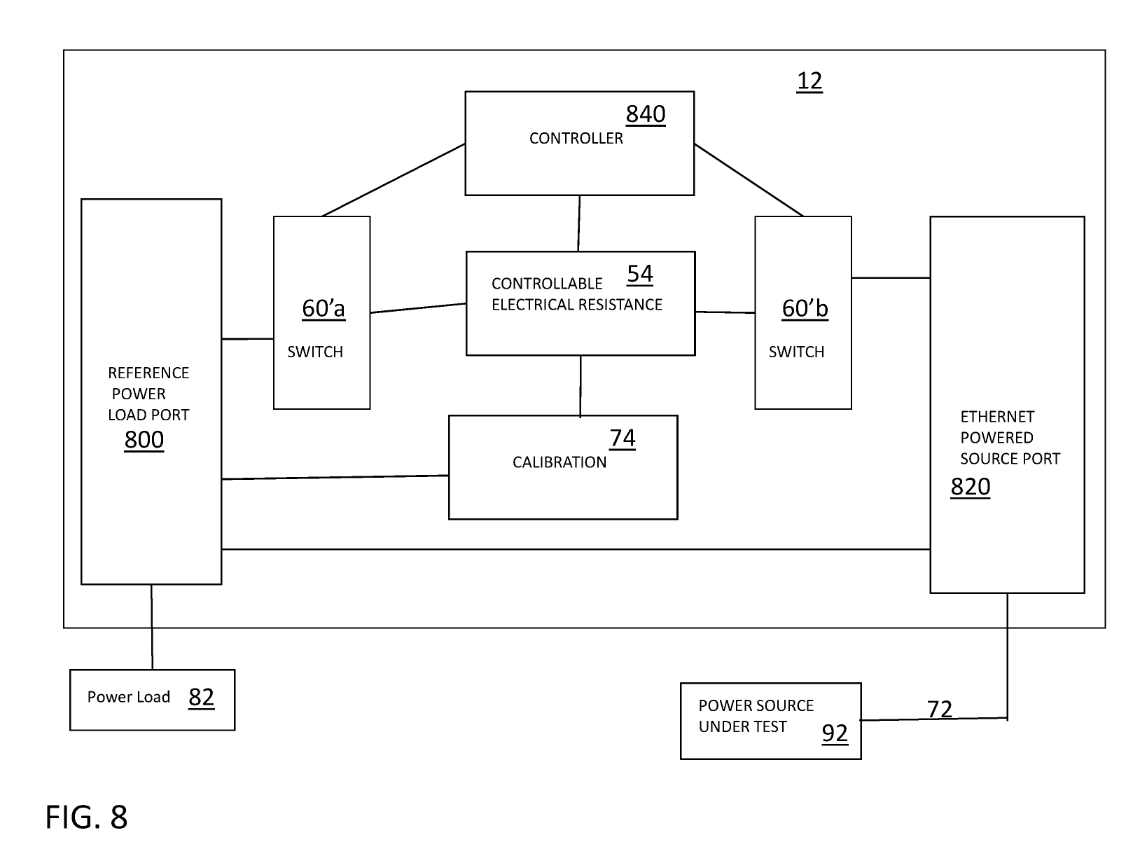

Now, referring to FIG. 8, in one embodiment, a system 12 to assess pair-to-pair unbalance characteristics of an Ethernet power source under test 92 (also referred to as the PSE under test 92) includes a controller 840 coupled to controllable electrical resistances 54, to a pair of switches 60′a and 60′b and to a calibration subsystem 74. The system 12 further includes a reference power load port 800 coupled to switch 60′a and an Ethernet power source port 820 coupled to switch 60′b. Switch 60′a selectively couples the controllable electrical resistances 54 to the reference power load port 800 and Switch 60′b selectively couples the controllable electrical resistances 54 to the Ethernet power source port 820. The system 12 further includes a reference power load 82 to provide a load to the PSE under test 92.

The calibration process uses an Ethernet patch cable 72 connecting the reference power load port 800 and the Ethernet power source port 820. The system 20 is able to accurately assess the pair-to-pair unbalance characteristics of the PSE under test 92 by calibrating the effects of the switches 60′a and 60′b, the Ethernet power source port 820, and the Ethernet patch cable 72. In one embodiment the controller 840 is a microcontroller and in another embodiment, the controller 840 is an interface to an external controlling device, for example, a computer.

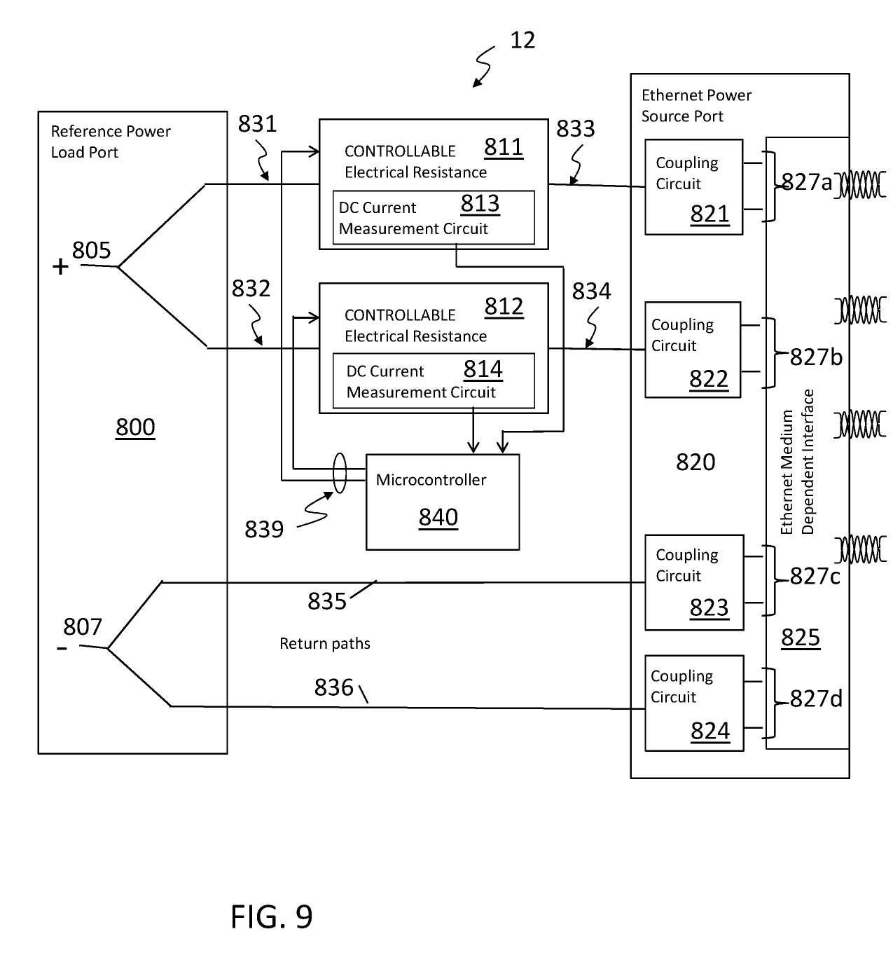

Now referring to FIG. 9, the system 12 to assess pair-to-pair unbalance characteristics of the PSE under test 92 of FIG. 8 includes in more detail the controller 840 coupled to the controllable electrical resistances 54 which includes a pair of controllable electrical resistances 811 and 812 each having an input port 833 and 834, a control port 839 coupled to the controller 840, output ports 831 and 832, and DC current measurement circuits 813 and 814. Each DC current measurement circuit 813 and 814 is configured to minimize an electrical resistance in a connection between the reference power load port 800 and the Ethernet power source port 820.

The reference power load port 800 further includes a first power load connection 805 having a first polarity coupled to both output ports 831 and 832 of the pair of controllable electrical resistances 811 and 812, respectively, and a second power load connection 807 having a second different polarity coupled to a pair of reference power load port return paths 835 and 836, respectively. The Ethernet power source port 820 further includes a first pair of Ethernet power source port coupling circuits 821 and 822, each coupled to corresponding input ports 833 and 834 of the pair of controllable electrical resistances 811 and 812, respectively, and a second pair of Ethernet power source port coupling circuits 823 and 824, each coupled to corresponding return paths 835 and 836 of the pair of reference power load port.

In operation during a test, a PoE load required for drawing current from a PSE-under-test is enabled by the reference power load port 800. In one embodiment of the reference power load port 800, the power load is provided by a power load external to the reference power load port 800 and the return current from the load. In another embodiment of the reference power load port 800, the power load is provided within the reference power load port 800. PoE power required for powering the power load (e.g., a simulated PD) is provided by the PSE under test 92 through the pair of controllable electrical resistances 811 and 812. In one embodiment of the reference power load port 800, the return current from the power load returns to the PSE via return paths 835 and 836 of the reference power load port 800.

The DC current measurement circuits 813 and 814 provide average and instantaneous measurements. The pair of controllable electrical resistances 811 and 812 is configurable to provide system load resistances for evaluating the Ethernet power source as described within an IEEE 802.3 clause 145 specification to create pair-to-pair resistance unbalance in wire pairs attached to the Ethernet power source port coupling circuits.

The components in the system 12 to assess the DC current unbalance produced by the Ethernet power source under test 92 while powering through four wire pairs include controllable electrical resistances 811 and 812. In order to produce controlled DC current unbalance, controllable electrical resistances 811 and 812 create resistance unbalance by being set to unmatched resistances. The controller 840 is utilized to configure each of the controllable electrical resistances 811, and 812, using control port 839 so that resistances may be rapidly reconfigured during testing.

In one embodiment, the controller 840 may facilitate system operation with an external computer and can have an internal graphical user interface (GUI) or the GUI can be supplied by the external computer (not shown) or an additional test instrument (not shown). In one embodiment, the controller 840 configures an electronically controllable resistance element. In another embodiment controller 840 actuates switching (not shown) to configure a set of fixed resistors.

The Ethernet powered source port 820 provides the system interface to the PSE under test 92, via the Ethernet patch cable 72. The Ethernet power source port 820 includes an Ethernet medium dependent interface (MDI) 825 and two coupling circuits 821 and 822, which receive DC current from the PSE under test 92 through the two wire pair connections 827a and 827b. The Ethernet power source port 820 includes two coupling circuits 823 and 824 which receive the return current which flows through wire pair connections 827c and 127d to the Ethernet patch cable 72 connected to the PSE under test 92. In one embodiment each coupling circuit 821, 822, 823 and 824 includes an Ethernet transformer with primary coil center taps (not shown) as is known in the art. Other embodiments may employ multiple magnetic coils in each coupling circuit in order to minimize DC resistance.

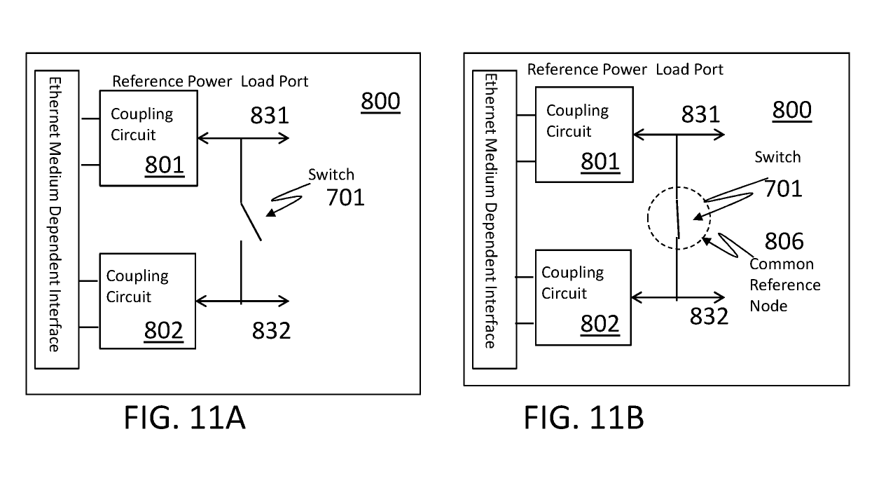

In one embodiment voltages are measured across a known portion of the controllable electrical resistances 811 and 812. These measurements are used to obtain DC current measurements without adding any uncontrolled resistance that would otherwise distort the expected pair-to-pair unbalance. In one embodiment, the electrical connections within the reference power load port 800, the pair of controllable electrical resistances 811 and 812, and the Ethernet power source port 820 are configured to add less than about 0.2 Ohms of uncontrolled series electrical resistance to a resistance produced by the controllable electrical resistances 811 and 812. In a further embodiment, this is accomplished by a combination of thick circuit board traces, the common reference node (described below in conjunction with FIGS. 11A and 11B), and redundant parallel connections in switches and coils. The controller 840 is utilized to configure each of the controllable electrical resistances 811 and 812 using control port 839 so that resistances may be rapidly reconfigured during testing. In one embodiment, the controller 840 configures an electronically controllable resistance element. In another embodiment, the controller 840 actuates switching to configure a set of fixed resistors.

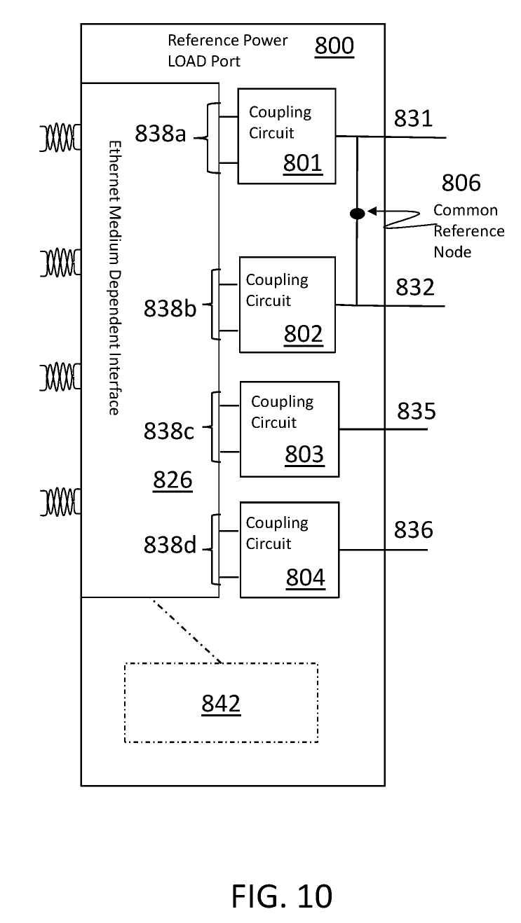

Referring to FIG. 10, the reference power load port 800 further includes a first pair of reference power load port coupling circuits 801 and 802, each coupled to corresponding output ports 831 and 832 of the pair of controllable electrical resistances 811 and 812, respectively, a second pair of reference power load port coupling circuits 803 and 804, each coupled to corresponding reference power load port return paths 835 and 836 respectively, and an Ethernet MDI 126 coupled to the first pair of reference power load port coupling circuits 801 and 802 and the second pair of reference power load port coupling circuits 803 and 804 via wire pair connections 838a-838d, respectively. In this configuration shown here, coupling circuit 801 is connected to output port 831, coupling circuit 802 is connected to output port 832, coupling circuit 803 is connected to return path 835 and coupling circuit 804 is connected to return path 836. The reference power load port 800 includes a common reference node 806, which in this configuration provides a low resistance connection between output port 831 and output port 832. The common reference node 806 assures that causes of DC resistance unbalance that might exist within the reference power load port 800 or in an external power load connected to the reference power load port 800 are greatly minimized so that there is almost no resistance unbalance between controllable electrical resistance output port 831 and output port 832. This means that the controllable electrical resistances 811 and 812, in tandem with the PSE under test 92, will govern the amount of DC current unbalance between wire pair connections 827a-827b at the Ethernet MDI 825 in the Ethernet power source port 820.

PoE power required for powering the power load (e.g., a simulated PD) is provided by the PSE under test 92 through the pair of controllable electrical resistances 811 and 812. In one embodiment of the reference power load port 800, the return current from the power load returns to PSE via return paths 835 and 836 of the reference power load port 800. In one embodiment, the coupling circuits 801-804 and the coupling circuits 821-824, include an Ethernet transformer with primary coil center taps.

In one embodiment source current is transferred to two wire pair connections 838a and 838b using coupling circuits 801 and 802 while return current from the PoE load is transferred to coupling circuits 803 and 804. In one embodiment of the reference power load port 800, the incoming current is returned from a power load external to the reference power load port 800 and the source current from the PSE under test 92 is fed to that same external power load. In another embodiment of the reference power load port 800, the incoming current is returned from an optional internal power load 842 to the reference power load port 800 and the source current from the PSE is fed into the same internal power load 842. In this embodiment, the coupling circuits 801, 802, 803, 804, 821, 822, 823 and 824 may comprise direct electrical connections.

Referring to FIGS. 11A and 11B, the reference power load port 800 further includes a switch 701 disposed between controllable electrical resistance output ports 831 and 832. Switch 701 swithcably connects the controllable electrical resistance output ports 831 and 832 together to create a common reference node 806. Switch 701 then allows the common reference node connection to be made after the simulated PD or actual PD 82 has been detected and classified by the PSE under test 92 which has entered a normal powering state of operation. This process prevents the common reference node 806 from interfering with the simulated or actual PD detection and classification processes that may precede application of operating power. In one embodiment, switch 701 further is deployed to prevent accidental connection of two wire pairs that are opposite voltage polarities. Common reference node 806 assures that any causes of DC resistance unbalance that might exist within the reference power load port 800, or in an external or internal load connected to the reference power load port 800 are completely negated so that there is no resistance unbalance between controllable electrical resistance output ports 831 and 832. This means that only the controllable electrical resistances 811 and 812, in tandem with the PSE under test 92, will govern the amount of DC current unbalance between wire pairs at the Ethernet MDI 825 in the Ethernet power source port 820. In one embodiment, switch 701 is open while PoE detection, classification, and power-up occurs between an external or internal powered load connected to the reference power load port 800, and the PSE under test 92 connected to the Ethernet Power Source Port 820, and then closed to provide the common reference node 806.

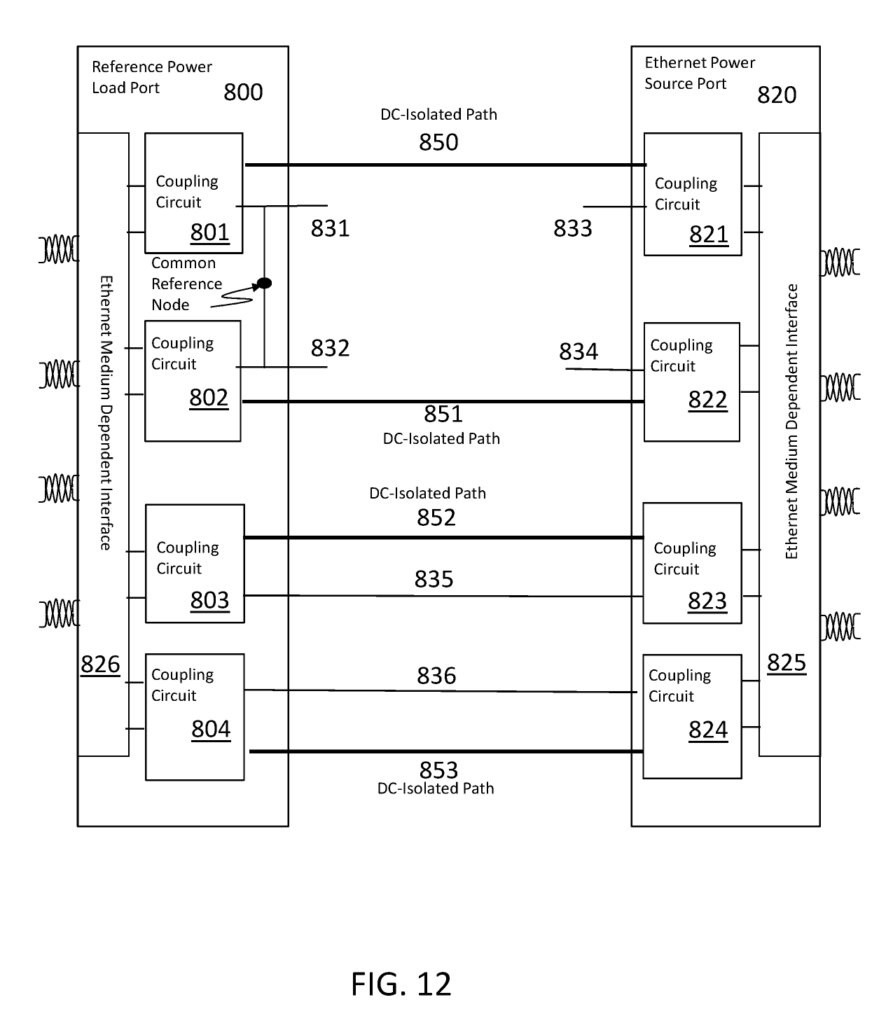

Now referring to FIG. 12 the system 12 further includes DC isolated paths 850, 851, 852, and 853 between coupling circuits 801, 802, 803, 804 and 821, 822, 823, 824, respectively, for transferring Ethernet data signaling between the reference power load port 800 and the Ethernet power source port 820. These DC isolated paths 850-853 provide a path for Ethernet data signaling between the reference load power port 800 and the Ethernet Power source port 820. In one embodiment, Ethernet data signaling is used to control the operating characteristics of the PSE under test 92. In a further embodiment, control of the operating characteristics of the PSE under test 92 may include negotiating power with PoE data-link layer classification. Control of operating characteristics of the PSE under test 92 can be essential to obtaining the highest possible current measurements.

The Ethernet medium dependent interface 826 enables the reference power load port 800 to connect with an external PoE Powered Device for PoE power loading. In one embodiment, the PD would be a PoE test instrument capable of loading 4-pair PoE power and forwarding LAN packet traffic. In one further embodiment, the PoE test instrument would have the capability to modify the magnitude of PoE loading.

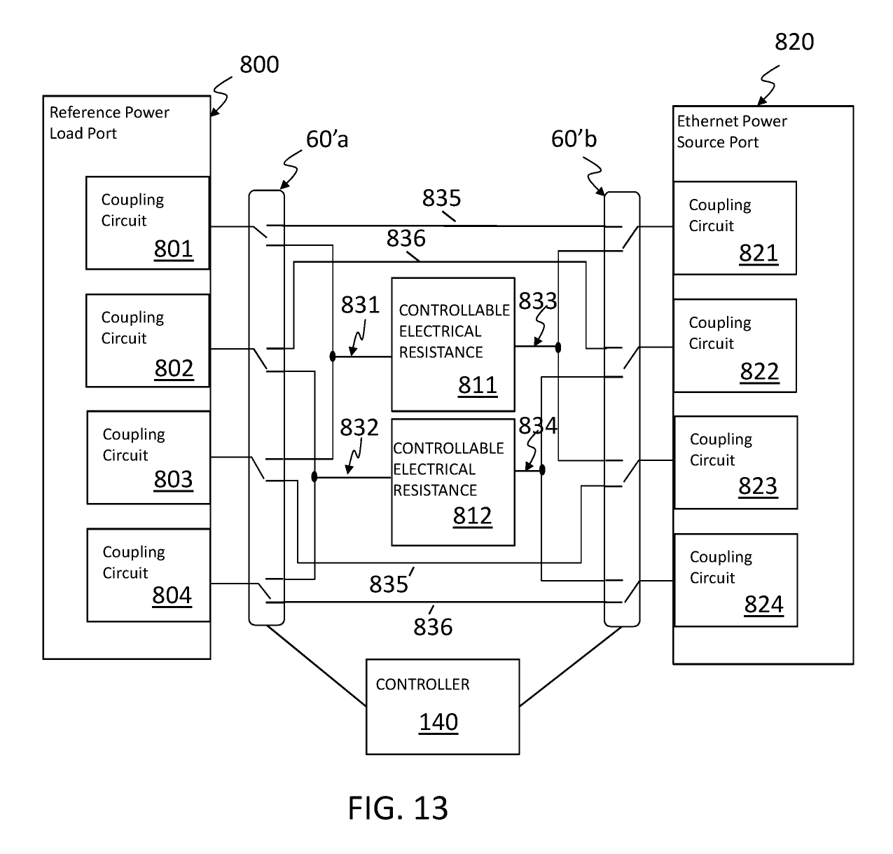

Now referring to FIG. 13, system 12 further includes a first switch 60′a coupled to the controller 840 to connect selected ones of the first pair of reference power load port coupling circuits 801 and 802 and selected ones of the second pair of reference power load port coupling circuits 803 and 804 to either the output ports 831 and 832 of selected ones of the pair of controllable electrical resistances 811 and 812 or selected ones of the pair of reference power load port return paths 835 and 836. System 12 further includes a second switch 60′b coupled to the controller 840 to connect selected ones of the first pair of Ethernet power port 820 coupling circuits 821 and 822 and selected ones of the second pair of Ethernet power source port coupling circuits 823 and 824 to either input ports 833 and 834 of selected ones of the pair of controllable electrical resistances 811 and 812 or to selected ones of the pair of reference power load port return paths 835 and 836.

In operation switches 60′a and 60′b connect controllable electrical resistance 811 between coupling circuits 801 and 821 or between coupling circuits 803 and 823 and connect controllable electrical resistance 812 between coupling circuits 802 and 822 or between coupling circuits 804 and 824. The selected switch settings connect the controllable electrical resistances 811 and 812 to paths of the same polarity when an unbalance assessment is made. Using switches 60′a and 60′b, each of the pair of controllable electrical resistances 811 and 812 is configurable to system source resistances for evaluating the PSE under test 92 in various wiring configurations as described within an IEEE 802.3 clause 145 specification to create pair-to-pair current resistance in wire pairs attached to the Ethernet power source coupling circuits 821-824.

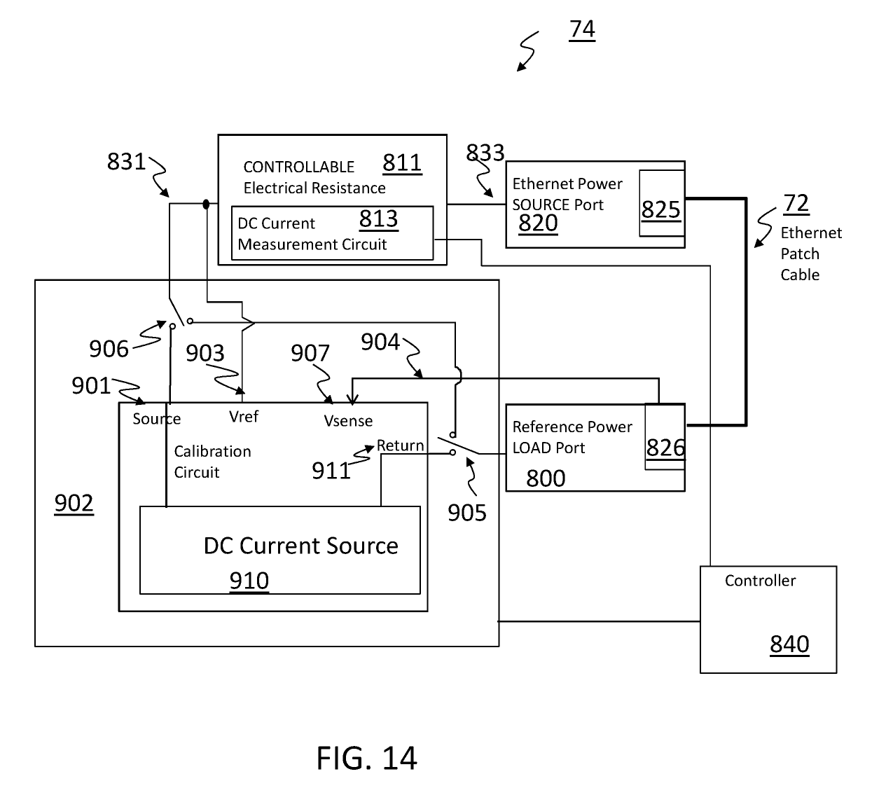

Now referring to FIG. 14, the calibration subsystem 74 of system 12 includes an Ethernet patch cable 72 coupling the reference power load port 800 and the Ethernet power source port 820; and a calibration circuit 902 coupled to the controller 840. The calibration circuit 902 also includes a DC current source 910 having a DC current source 901 (also referred to as DC current source connection 901 and a DC current return 911 (also referred to as DC current return connection 911), to provide at least one current level, here, to the controllable electrical resistance 811. The calibration circuit 902 further includes a switch 906 to selectively couple the controllable electrical resistance 811 output port 831 to the DC current source connection 901, and a switch 905 to selectively couple at least one coupling circuit (801-804) within the reference power load port 800 to the DC current return connection 911. Switches 905 and 906 interrupt the normal connection between the reference power load port 800 and the output port 831 of the controllable electrical resistance 811 to insert the calibration circuit 802. The calibration circuit 802 further includes a pair of voltage sense inputs (voltage sense input 907 and a voltage reference input 903) that are used to measure a voltage drop from the Ethernet MDI 826 in the reference power load port 800 and the output port 831 of the controllable electrical resistance 811. In a further embodiment of the calibration subsystem 74, additional switches within the calibration circuit 902 would allow the DC current source 310 to be connected to the output port 832 of controllable electrical resistance 812 and to a different coupling circuit within the reference power load port 800.

In operation, the calibration circuit 902 provides DC current source connection 901 and DC current return connection 911, through which a DC current passes and the calibration circuit 902 measures an actual electrical resistance of the controllable electrical resistance 811, the Ethernet power source port 820, and the Ethernet patch cable 72. The source 900 is connected to the output port 831 of the controllable electrical resistance 811. The input 833 of the controllable electrical resistance 811 passes the current to one of the coupling circuits 821, 823 of the Ethernet Power source port 820, which passes the current through one of the wire pairs of an Ethernet patch cable 72. The Ethernet patch cable 72 is connected between the Ethernet power source Port 820 and the Reference power load port 800. The current passes through the Ethernet patch cable 72, the Reference Power load Port 800, and to the DC current return connection 911 connection at the calibration circuit 802. Voltage is sensed at the Ethernet MDI 826, to determine a total voltage drop between the output port 831 of the controllable electrical resistance 111 and the end of the Ethernet patch connected to the MDI 826 in the reference power load port 800. The DC current is measured by the DC current measurement circuit 813, connected to the controller 840. The DC current result is sent to the calibration circuit 902.

The total voltage drop is then combined with the DC current measurement to compute the actual electrical resistance between the output port 831 of the controllable electrical resistance 811 and the end of the Ethernet patch cable 72 connected to the reference power load port 800. In a further embodiment of the calibration subsystem, a similar process is used to measure the actual electrical resistance between the output port 832 of the controllable electrical resistance 812 and the end of the Ethernet patch cable 72 connected to the MDI 826 in the reference power load port 800. The actual resistances measured may then be subsequently applied during pair-to-pair unbalance testing of the PSE under test 92 to adjust measured DC unbalance currents to compensate for any uncontrolled resistances present in electrical connections, the Ethernet power source port 820 and the Ethernet patch cable 72.

DC current is measured by the DC current measurement circuit 813, connected to the calibration circuit 902, sends to the DC current result to the calibration circuit 902. The total resistance of the controllable electrical resistance 811, the Ethernet Power Source Port 820, the Reference Power load Port 800, and the Ethernet patch cable 72, is determined with the Vref and Vsense results.

It is understood that the systems 10 and 12 can interface to other test systems which can provide power, loads, communications with equipment under test and user interfaces. It will be apparent to those skilled in the art that various changes and modifications may be implemented which fall within the spirit of the invention. The embodiments and examples described herein should be considered exemplary and not restrictive or limiting, and that the scope of the method and system described herein is determined by the appended claims and their equivalents.

It is understood, that the embodiments described above can be implemented as a standalone instrument performing individual tests, a combined test instrument performing multiple tests or a test system. The above-described embodiments can be implemented in any of numerous ways. For example, the embodiments may be implemented using hardware, software or a combination thereof. When implemented in software, the software code can be executed on any suitable processor or collection of processors, whether provided in a single computer or distributed among multiple computers.

The various methods or processes outlined herein may be coded as software that is executable on the controllers 140 and 840 which might include one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs including computer readable instructions that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular data types. Typically the functionality of the program modules may be combined or distributed as desired in various embodiments. Aforementioned examples are not exhaustive, and are for illustration and not limitation.

The computer program(s) may be implemented using one or more high level procedural or object-oriented programming languages to communicate with a computer system; however, the program(s) may be implemented in assembly or machine language, if desired. The language may be compiled or interpreted.

As provided herein, the controller(s) may thus be embedded in one or more devices that may be operated independently or together in a networked environment, where the network may include, for example, a Local Area Network (LAN), wide area network (WAN), and/or may include an intranet and/or the internet and/or another network. The network(s) may be wired or wireless or a combination thereof and may use one or more communications protocols to facilitate communications between the different processors. The processors may be configured for distributed processing and may utilize, in some embodiments, a client-server model as needed. Accordingly, the methods and systems may utilize multiple processors and/or processor devices, and the processor instructions may be divided amongst such single- or multiple-processor/devices.

References to “a controller,” or “a microcontroller,” may be understood to include one or more microprocessors that may communicate in a stand-alone and/or a distributed environment(s), and may thus be configured to communicate via wired or wireless communications with other processors, where such one or more processor may be configured to operate on one or more processor-controlled devices that may be similar or different devices. Use of such “processor” terminology may thus also be understood to include a central processing unit, an arithmetic logic unit, an application-specific integrated circuit (IC), and/or a task engine, with such examples provided for illustration and not limitation.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein. Although the methods and systems have been described relative to a specific embodiment thereof, they are not so limited. Obviously many modifications and variations may become apparent in light of the above teachings. Many additional changes in the details, materials, and arrangement of parts, herein described and illustrated, may be made by those skilled in the art.

It will be apparent to those skilled in the art that various changes and modifications may be implemented which fall within the spirit of the invention. The embodiments and examples described herein should be considered exemplary and not restrictive or limiting, and that the scope of the method and system described herein is determined by the appended claims and their equivalents.

It is understood, that the embodiments described above can be implemented as a standalone instrument performing individual tests, a combined test instrument performing multiple tests or a test system.

The above-described embodiments can be implemented in any of numerous ways. For example, the embodiments may be implemented using hardware, software or a combination thereof. When implemented in software, the software code can be executed on any suitable processor or collection of processors, whether provided in a single computer or distributed among multiple computers.

The various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

Furthermore, references to memory, unless otherwise specified, may include one or more processor-readable and accessible memory elements and/or components that may be internal to the processor-controlled device, external to the processor-controlled device, and/or may be accessed via a wired or wireless network using a variety of communications protocols, and unless otherwise specified, may be arranged to include a combination of external and internal memory devices, where such memory may be contiguous and/or partitioned based on the application.

Throughout the entirety of the present disclosure, use of the articles “a” or “an” to modify a noun may be understood to be used for convenience and to include one, or more than one of the modified noun, unless otherwise specifically stated.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein. Although the methods and systems have been described relative to a specific embodiment thereof, they are not so limited. Obviously many modifications and variations may become apparent in light of the above teachings. Many additional changes in the details, materials, and arrangement of parts, herein described and illustrated, may be made by those skilled in the art.

What is claimed is:

1. A system to assess pair-to-pair unbalance characteristics of an Ethernet powered device (PD) under test comprising:
a controller;
a pair of controllable electrical resistances, each having an input port, a control port coupled to the controller, an output port, and a DC current measurement circuit;
a reference power input port comprising:
a first power supply input connection having a first polarity coupled to both input ports of the pair of controllable electrical resistances and
a second power supply input connection having a second different polarity coupled to a pair of reference power input port return paths;
an Ethernet powered device port comprising:
a first pair of Ethernet powered device port coupling circuits, each coupled to corresponding output ports of the pair of controllable electrical resistances; and
a second pair of Ethernet powered device port coupling circuits, each coupled to corresponding return paths in the reference power input port.

2. The system of claim 1, wherein each DC current measurement circuit is disposed to minimize an electrical resistance in a connection between the reference power input port and the Ethernet powered device port.

3. The system of claim 1 wherein the reference power input port further comprises:
a first pair of reference power input port coupling circuits, each coupled to corresponding input ports of the pair of controllable electrical resistances;
a second pair of reference power input port coupling circuits, each coupled to corresponding reference power input port return paths; and
an Ethernet MDI coupled to the first pair of reference power input port coupling circuits and the second pair of reference power input port coupling circuits.

4. The system of claim 3, further comprising a switch to selectively connect each one of the first pair of reference power input port coupling circuits to a common reference node.

5. The system of claim 3, further comprising at least one DC-Isolated path disposed between each reference power input port coupling circuit and each corresponding Ethernet powered device port coupling circuit, for transferring Ethernet data signaling between the reference power input port and the Ethernet powered device port.

6. The system of claim 3, further comprising:
a first switch coupled to the controller to connect selected ones of the first pair of reference power input port coupling circuits and selected ones of the second pair of reference power input port coupling circuits to one of:
input ports of selected ones of the pair of controllable electrical resistances; and
selected ones of the pair of reference power input port return paths;
a second switch coupled to the controller to connect selected ones of the first pair of Ethernet powered device port coupling circuits and selected ones of the second pair of Ethernet powered device port coupling circuits to one of:
output ports of selected ones of the pair of controllable electrical resistances; and
selected ones of the pair of reference power input port return paths.

7. The system of claim 3, further comprising;
an Ethernet patch cable coupling the reference power input port and the Ethernet powered device port; and
a calibration circuit coupled to the controller comprising;
a switch selectively coupling an input port of at least one of the pair of controllable electrical resistances to a source connection of the calibration circuit; and
a switch selectively coupling a return connection in the calibration circuit to at least one coupling circuit in the reference power input port; and
a pair of voltage sense inputs to measure a voltage drop between an input port of a same one of the pair of controllable electrical resistances and the Ethernet MDI in the reference power input port.

8. The system of claim 7 wherein the calibration circuit further includes at least one DC current source to insert a DC current into the source connection and to receive the DC current from the return connection.

9. The system of claim 1, wherein each of the pair of controllable electrical resistances is configurable to system source resistances for evaluating the Ethernet powered device as described within an IEEE 802.3 clause 145 specification to create pair-to-pair current unbalance in wire pair connections of the same voltage polarity attached to the Ethernet powered device port coupling circuits; and
wherein each DC Current Measurement circuit provides at least one of average and instantaneous measurements.

10. The system of claim 1, wherein electrical connections within the reference power input port, the pair of controllable electrical resistances, and the Ethernet powered device port are configured to add less than about 0.2 Ohms series electrical resistance to a resistance produced by at least one of the pair of controllable electrical resistances.

11. A system to assess pair-to-pair unbalance characteristics of an Ethernet power source under test comprising:
a controller;
a pair of controllable electrical resistances, each having an input port, a control port coupled to the controller, an output port, and a DC current measurement circuit;
a reference power load port comprising:
a first power load connection having a first polarity coupled to both output ports of the pair of controllable electrical resistances and
a second power load connection having a second different polarity coupled to a pair of reference power load port return paths;
an Ethernet power source port comprising:
a first pair of Ethernet power source port coupling circuits, each coupled to corresponding input ports of the pair of controllable electrical resistances; and
a second pair of Ethernet power source port coupling circuits, each coupled to corresponding return paths of the pair of reference power load port return paths.

12. The system of claim 11, wherein each DC current measurement circuit is disposed to minimize an electrical resistance in a connection between the reference power load port and the Ethernet power source port.

13. The system of claim 11, wherein the reference power load port further comprises:
a first pair of reference power load port coupling circuits, each coupled to corresponding output ports of the pair of controllable electrical resistances;
a second pair of reference power load port coupling circuits, each coupled to corresponding reference power load port return paths; and
an Ethernet MDI coupled to the first pair of reference power load port coupling circuits and the second pair of reference power load port coupling circuits.

14. The system of claim 13, further comprising a switch to selectively connect each one of the first pair of reference power load port coupling circuits to a common reference node.

15. The system of claim 13, further comprising at least one DC-Isolated path disposed between each corresponding reference power load port coupling circuit and each corresponding Ethernet power source port coupling circuit for transferring Ethernet data signaling between the reference power load port and the Ethernet power source port.

16. The system of claim 13, further comprising:
a first switch coupled to the controller to connect selected ones of the first pair of reference power load port coupling circuits and selected ones of the second pair of reference power load port coupling circuits to one of:
output ports of selected ones of the pair of controllable electrical resistances; and
selected ones of the pair of reference power load port return paths;
a second switch coupled to the controller to connect selected ones of the first pair of Ethernet power source port coupling circuits and selected ones of the second pair of Ethernet power source port coupling circuits to one of:
input ports of selected ones of the pair of controllable electrical resistances; and
selected ones of the pair of reference power load port return paths.

17. The system of claim 13, further comprising;
an Ethernet patch cable coupling the reference power load port and the Ethernet power source port; and
a calibration circuit coupled to the controller comprising;
a switch selectively coupling an output port of at least one of the pair of controllable electrical resistances to a source connection of the calibration circuit; and
a switch selectively coupling a return connection in the calibration circuit to at least one coupling circuit in the reference power load port; and
a pair of voltage sense inputs to measure a voltage drop between an output port of a same one of the pair of the controllable electrical resistances and the Ethernet MDI in the reference power load port.

18. The system of claim 17 wherein the calibration circuit further includes at least one DC current source to insert a DC current into the source connection and to receive the DC current from the return connection.

19. The system of claim 11, wherein each of the pair of controllable electrical resistances are configurable to provide system load resistances for evaluating the Ethernet power source as described within an IEEE 802.3 clause 145 specification to create a pair-to-pair current unbalance in wire pair connections of the same voltage polarity attached to the Ethernet power source port coupling circuits; and
wherein each DC Current Measurement circuit provides at least one of an average and an instantaneous measurement.

20. The system of claim 11, wherein electrical connections within the reference power load port, the pair of controllable electrical resistances and the Ethernet power source port are configured to add less than about 0.2 Ohms series electrical resistance to a resistance produced by at least one of the pair of controllable electrical resistances.
